(19) United States
(12) Patent Application Publication
(10) Pub. No.: US 2026/0153556 A1
(43) Pub. Date: Jun. 4, 2026

(54) DETERMINING SPEAKER STATUS USING BACK EMF CHANGES

(71) Applicant: TEXAS INSTRUMENTS INCORPORATED, Dallas, TX (US)

(72) Inventors: David VASELIOU, Dallas, TX (US); Jasjot CHADHA, Allen, TX (US); Douglas A. ROBERSON, Royse City, TX (US); Supriyo PALIT, Richardson, TX (US)

(21) Appl. No.: 18/963,995

(22) Filed: Nov. 29, 2024

(51) Int. Cl. G01R 31/28; H04R 29/00

(52) U.S. Cl. CPC G01R 31/2825; H04R 29/001

(57) ABSTRACT

In examples, a device includes audio amplifier circuitry having an input and an output. The output is configured to couple to a speaker. The device also includes sense circuitry coupled to the output and configured to sense a voltage and a current of an analog audio signal from the audio amplifier circuitry. The current indicates a back electromotive force (EMF) of the speaker. The device also includes processing circuitry coupled to the sense circuitry, which is configured to calculate an impedance of a speaker based on the voltage and the current, compare the impedance to a target impedance, and indicate an operational status of the speaker responsive to the comparison.

### BACKGROUND

Speakers in audio systems convert electrical signals into sound by moving a diaphragm, usually in the form of a cone or dome, to create sound waves. When driven by an audio signal, a voice coil of the speaker moves within a magnetic field, causing the diaphragm to produce variations in air pressure that generate sound. Frequency range, sensitivity, and impedance impact the ability of a speaker to reproduce sound accurately and at different volumes.

### SUMMARY

In examples, a device includes audio amplifier circuitry having an input and an output, with the output configured to couple to a speaker. The device also includes sense circuitry coupled to the output and configured to sense a voltage and a current of an analog audio signal from the audio amplifier circuitry. The current indicates a back electromotive force (EMF) of the speaker. The device also includes processing circuitry coupled to the sense circuitry, which is configured to calculate an impedance of a speaker based on the voltage and the current, compare the impedance to a target impedance, and indicate an operational status of the speaker responsive to the comparison.

In examples, a non-transitory, computer-readable medium stores instructions, which, when executed by a processor, cause the processor to receive a first current signal from an input of a speaker in an audio device. The first current signal indicates a first back electromotive force (EMF) produced by the speaker responsive to a first attempt to emit a sound. The instructions cause the processor to receive a second current signal from the input of the speaker. The second current signal indicates a second back EMF produced by the speaker responsive to a second attempt to emit the sound. The instructions cause the processor to calculate a first impedance based on the first current signal and on a first voltage signal indicating a first voltage at the input of the speaker, calculate a second impedance based on the second current signal and on a second voltage signal indicating a second voltage at the input of the speaker, compare the first and second impedances, and indicate an operational status of the audio device responsive to the comparison.

### BRIEF DESCRIPTION OF THE DRAWINGS

FIG. 1 is a block diagram of an electronic system including an audio device to determine a speaker status using back electromotive force (EMF) changes, in various examples.

FIG. 2 is a block diagram of an audio device to determine a speaker status using back EMF changes, in various examples.

FIG. 3 is a circuit schematic diagram of an audio device to determine a speaker status using back EMF changes, in various examples.

FIG. 4 is a flow diagram of a method for determining a speaker status using back EMF changes, in various examples.

FIG. 5 is a graph depicting an impedance profile that indicates back EMF changes useful to determine a speaker status, in various examples.

FIG. 6 is a graph depicting an impedance profile that indicates back EMF changes useful to determine a speaker status, in various examples.

### DETAILED DESCRIPTION

In audio systems, speakers may experience various malfunctions that affect sound quality and performance. These malfunctions can include issues such as distortion, degradation over time, or physical damage to components, all of which alter the expected audio output. To facilitate consistent performance, speakers may be repeatedly evaluated to detect any deviation from a target behavior. One method for detecting malfunctions is to capture audio samples from the speaker and compare them to predetermined target samples that represent the correct audio output. By comparing the real-time audio output to these reference samples, discrepancies in sound can indicate potential malfunctions. Identifying such discrepancies allows for timely intervention, helping maintain audio quality.

A common approach for implementing this monitoring technique is to place a microphone near the speaker to capture its audio output. The captured audio samples can then be analyzed against the target samples to assess fidelity. However, adding a microphone solely for this monitoring function presents challenges in terms of cost and space within the audio system. The inclusion of a dedicated microphone requires additional hardware, which increases production costs and requires space allocation that may be impractical in compact or integrated designs. As a result, developing alternative methods to monitor speaker performance without relying on an extra microphone could provide more cost-effective and space-efficient solutions.

This description presents various examples of an audio device that mitigates the challenges described above by monitoring a speaker input for changes in the speaker back EMF and indicating that the speaker may be defective responsive to detecting such a change. More specifically, the audio device may include a speaker and a digital signal processor (DSP) that collects, or is programmed with, a baseline impedance profile of that speaker when the speaker is operating normally. The impedance profile depicts the impedance at the input to the speaker over a range of audio signal frequencies, which may include the resonance frequency of the speaker. Because the impedance at the input to the speaker is calculated using the sensed current and voltage at the input to the speaker, and further because the back EMF of the speaker is included in the sensed current, the impedance reflects the degree of back EMF being provided by the speaker. The DSP may then receive the sensed current and voltage from the input to the speaker across a range of frequencies, determine a second impedance profile, and compare the second impedance profile against the baseline impedance profile to identify any differences between the impedance profiles. Any such difference between the impedance profiles may indicate that the speaker is defective, because load defects (e.g., speaker short circuits) may cause a change in the back EMF that the speaker provides at the speaker input. A change in the back EMF, in turn, may result in a change in the impedance profile. A mismatch between impedance profiles also may indicate that the audio signal provided to the speaker was not the target audio signal encoded in the baseline impedance profile. Accordingly, leveraging back EMF, which is already present at the speaker input and which indicates the presence of a speaker defect (or an incorrect audio signal being supplied to the speaker), is an inexpensive and space-conserving alternative to the use of additional microphones to detect speaker malfunctions.

In examples, the DSP receives a first current signal from an input of a speaker in an audio device, the first current signal indicating a first back electromotive force (EMF) produced by the speaker responsive to a first attempt to emit a sound. The first current signal may be received from the input of the speaker during a training session in which the speaker is known to be operating normally. The DSP may subsequently receive a second current signal from the input of the speaker after the training session is complete and when the operational status of the speaker is unknown. The second current signal indicates a second back EMF, if any, produced by the speaker responsive to a second attempt to emit the sound. The DSP may calculate a first impedance based on the first current signal and on a first voltage signal indicating a first voltage at the input of the speaker. The DSP may calculate a second impedance based on the second current signal and on a second voltage signal indicating a second voltage at the input of the speaker. The DSP may compare the first and second impedances. The DSP may indicate an operational status of the audio device responsive to the comparison.

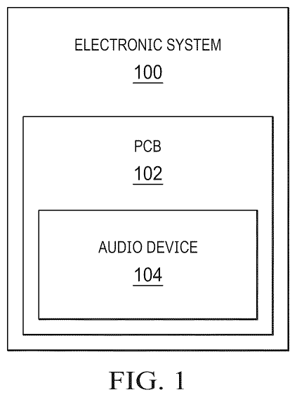

FIG. 1 is a block diagram of an electronic system including an audio device to determine a speaker status using back EMF changes, in various examples. Specifically, FIG. 1 is a block diagram of an electronic system 100 that includes a printed circuit board (PCB) 102 and an audio device 104 coupled to the PCB 102. Examples of the electronic system 100 include an automobile, an aircraft, a watercraft, a spacecraft, a video game console, a smartphone, an entertainment device, a stereo system, an appliance, a laptop computer, a desktop computer, a tablet, a notebook, or any other suitable type of electronic device or system. The audio device 104 may be any suitable audio subsystem, device, circuitry, or executable instructions that result in the production of sound, such as an audio system in a laptop computer or an automobile. Other examples of the electronic system 100 and the audio device 104 are contemplated and included in the scope of this description.

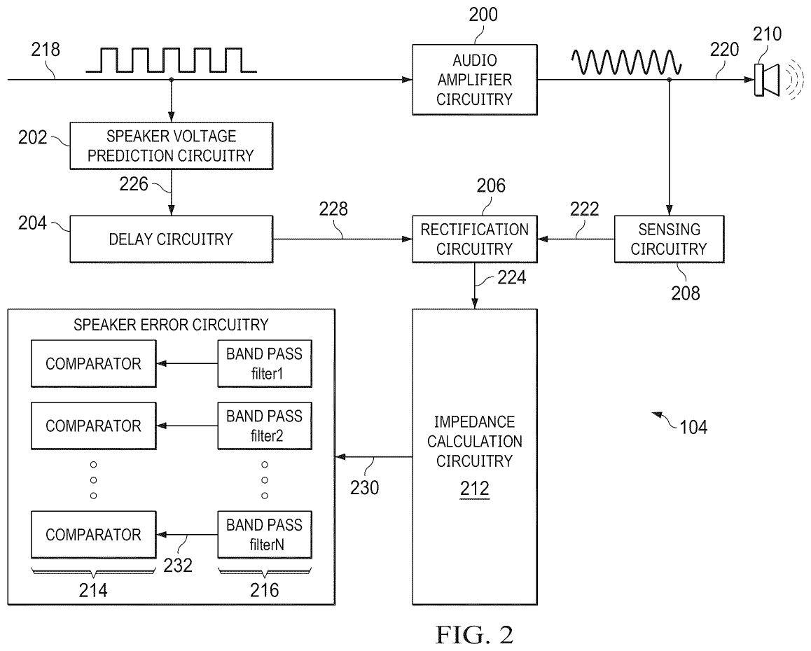

FIG. 2 is a block diagram of an audio device to determine a speaker status using back EMF changes, in various examples. More specifically, FIG. 2 is an example of the audio device 104 in FIG. 1. The example audio device 104 includes audio amplifier circuitry 200, speaker voltage prediction circuitry 202, delay circuitry 204, rectification circuitry 206, sensing circuitry 208, a speaker 210, impedance calculation circuitry 212, comparator circuitry 214, and bandpass filter circuitry 216. A connection 218 is coupled to inputs of the audio amplifier circuitry 200 and the speaker voltage prediction circuitry 202. A connection 220 is coupled to an output of the audio amplifier circuitry 200 and to inputs of the speaker 210 and the sensing circuitry 208. A connection 222 is coupled to an output of the sensing circuitry 208 and to an input of the rectification circuitry 206. A connection 224 is coupled to an output of the rectification circuitry 206 and to an input of the impedance calculation circuitry 212. A connection 226 is coupled to an output of the speaker voltage prediction circuitry 202 and to an input of delay circuitry 204. A connection 228 is coupled to an output of the delay circuitry 204 and to an input of the rectification circuitry 206. A connection 230 is coupled to an output of the impedance calculation circuitry 212 and to inputs of bandpass filter circuitry 216. Connection(s) 232 are coupled to outputs of the bandpass filter circuitry 216 and to inputs of the comparator circuitry 214.

In operation, the audio amplifier circuitry 200 receives a digital signal via the connection 218. The audio amplifier circuitry 200 processes the digital signal by performing any of a variety of suitable operations on the signal, including conversion from the digital domain to the analog domain and amplification of the resulting analog signal. The audio amplifier circuitry 200 provides the amplified analog signal on the connection 220. The amplified analog signal drives the speaker 210. The sensing circuitry 208 senses parameters of the amplified analog signal, such as the voltage and the current of the amplified analog signal driving the speaker 210. The current on the connection 220, which the sensing circuitry 208 measures, is affected by the back EMF of the speaker 210. Stated another way, when the speaker 210 emits sound, a physical coil of the speaker 210 moves and interacts with the surrounding magnetic field. As a result, a voltage is generated, and this voltage opposes the current driving the speaker 210. As a result, the degree of back EMF and changes in back EMF can be assessed by measuring the current driving the speaker 210.

The sensing circuitry 208 provides the sensed currents and voltages to the rectification circuitry 206 via the connection 222. Because alternating current (AC) signals vary with time and can be out of phase with each other, direct comparisons between two or more AC signals can be complex and lead to inaccurate results. Accordingly, the rectification circuitry 206 rectifies the current and voltage signals received from the connection 222, meaning that the rectification circuitry 206 performs an absolute value operation on the current and voltage signals received from the connection 222. The rectification circuitry 206 provides the rectified current and voltage signals to the impedance calculation circuitry 212 via the connection 224. The impedance calculation circuitry 212 calculates an impedance signal based on the rectified current and voltage signals.

Currents and voltages may be continuously present on the connection 220 and may vary with time to drive the speaker 210 to produce differing frequencies and volumes. The impedance calculation circuitry 212 continuously receives these current and voltage signals (in rectified form) and continuously produces impedance calculations based on the received current and voltage signals. Thus, the current, voltage, and impedance signals may be considered as continuously generated curves that vary with time depending on the volume and frequency of sounds emitted by the speaker 210, as well as the back EMF generated by the speaker 210.

The continuous stream of impedance values provided by the impedance calculation circuitry 212 is filtered according to frequency band, such as by the bandpass filter circuitry 216. After the impedance signal has been filtered by frequency band, the resulting impedance value for each frequency band is compared to a target impedance value. The target impedance value for a given frequency band may be obtained from a baseline impedance profile calculated using current and voltage values that were sensed when the speaker 210 was known to be operating properly. To facilitate a like-for-like comparison, the sound emitted by the speaker 210 to generate the baseline impedance profile is the same sound that the speaker 210 attempts to emit during operation. Thus, for instance, the speaker 210 may emit a predetermined sound that ranges in frequency from 250 Hz to 1 kHz, and the resulting range of sensed current and voltage values are used to calculate a corresponding range of impedance values. The calculated range of impedance values for the specific sound that was played by the speaker 210 at a frequency ranging from 250 Hz to 1 kHz forms an example baseline impedance profile. Accordingly, the baseline impedance profile is defined as a range of impedance values for a specific range of frequencies used to generate a particular sound by the speaker 210. The baseline impedance profile may be characterized by a curve plotting impedance as a function of frequency. After the baseline impedance profile has been generated, the same sound used to generate the baseline impedance profile may be played (or attempted to be played) on the speaker 210. If the resulting impedances match those of the baseline impedance profile, then the back EMF has not changed, meaning that the speaker 210 is operating properly. However, if the speaker 210 has ceased operating properly, the movement of the coil in the speaker 210 may be altered, resulting in a different driving current at the speaker 210 input and hence a difference impedance profile. This difference is detected by the comparator circuitry 214, indicating that the speaker 210 is defective. Alternatively, such a difference may indicate that the speaker 210 is operating properly, but that the incorrect sound was played, suggesting a fault or error in the signal processing circuitry that drives the speaker 210.

The baseline impedance profile may be useful to determine the reference values provided at the reference value inputs to the comparator circuitry 214. For example, if a set of impedances for the frequency range 250 Hz to 1 kHz is bandpass filtered and the target impedance value for a frequency range of 250 Hz to 350 Hz is 5.5 ohms to 6.0 ohms, the output of the bandpass filter is coupled to a first comparator receiving a reference signal corresponding to 5.5 ohms, and to a second comparator receiving a reference signal corresponding to 6.0 ohms. The inputs to the first and second comparators are configured so that the pair of comparators issue a binary HIGH output signal responsive to the impedance being outside of the 5.5 ohms to 6.0 ohms range.

In at least some examples, one or more of the bandpass filters in the bandpass filter circuitry 216 includes the resonance frequency range of the speaker 210. Changes in the speaker 210 back EMF (e.g., due to speaker faults) affect the impedance(s) of the speaker 210 most prominently at and near the resonant frequency of the speaker 210. Thus, comparing the speaker 210 impedance against the baseline impedance profile at and near the resonant frequency of the speaker 210 is an effective approach to detecting speaker faults and other operational problems.

In some examples, the voltage at the input of the speaker 210 is not sensed. Rather, the speaker voltage prediction circuitry 202 predicts the voltage at the input of the speaker 210. In particular, the speaker voltage prediction circuitry 202 obtains the voltage provided to the audio amplifier circuitry 200 to drive the speaker 210. Because the back EMF of the speaker 210 does not significantly alter the voltage at the input of the speaker 210, and the audio amplifier circuitry 200 applies a linear amplification to the digital signal received via the connection 218, the voltage prediction circuitry 202 can determine a proxy for the voltage sensed at the input of the speaker 210 from the digital signal received via the connection 218. The delay circuitry 204 applies a delay to the predicted voltage signal provided by the speaker voltage prediction circuitry 202, because the predicted voltage signal is phase-shifted (e.g., ahead in time) relative to the sensed voltage signal at the input of the speaker 210. The specific delay applied by the delay circuitry 204 is application-specific. The delay circuitry 204 provides the delayed, predicted voltage signal to the rectification circuitry 206 via the connection 228.

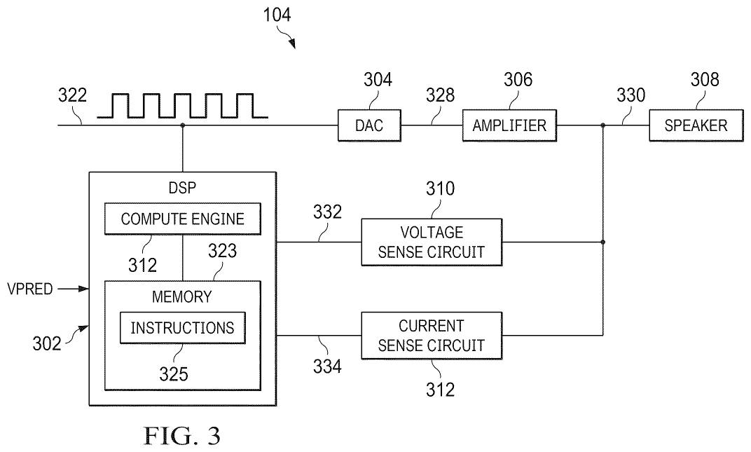

FIG. 3 is a circuit schematic diagram of an audio device to determine a speaker status using back EMF changes, in various examples. In particular, FIG. 3 depicts an example audio device 104 including a digital signal processor (DSP) 302, a digital-to-analog converter (DAC) 304, an amplifier 306, a speaker 308, a voltage sense circuit 310, and a current sense circuit 312. The example audio device 104 also includes a compute engine 321, a memory 323 (e.g., a non-transitory memory, such as random access memory (RAM) or read-only memory (ROM)), and instructions 325 stored on the memory 323.

A connection 322 is coupled to an input of the DSP 302 and to an input of the DAC 304. A connection 328 couples an output of the DAC 304 to an input of the amplifier 306. A connection 330 couples an output of the amplifier 306 to an input of the speaker 308. The connection 330 also couples the output of the amplifier 306 and the input of the speaker 308 to inputs of the voltage sense circuit 310 and the current sense circuit 312. A connection 332 couples an output of the voltage sense circuit 310 to an input of the DSP 302. A connection 334 couples an output of the current sense circuit 312 to an input of the DSP 302.

The operation of the example audio device 104 in FIG. 3 is similar to that described above for the example audio device 104 in FIG. 2. The DSP 302 receives digital signals from connections 322, 332, and 334 and performs at least some of the operations attributed herein to the rectification circuitry 206, the impedance calculation circuitry 212, the comparator circuitry 214, and the bandpass filter circuitry 216. The DSP 302 performs at least some operations as a result of the compute engine 321 executing the instructions 325. The DAC 304 and the amplifier 306 perform some of the operations attributed herein to the audio amplifier circuitry 200. The voltage sense circuit 310 and the current sense circuit 312 perform operations attributed herein to the sensing circuitry 208.

The connection 322 provides a digital signal (e.g., an audio signal) to the DSP 302. The DSP 302 receives the digital signal from the connection 322, processes the digital signal in any suitable manner. The DAC 304 converts the digital signal to the analog domain. The amplifier 306 receives the analog signal via the connection 328. The amplifier 306 applies a gain to the analog signal and provides the amplified signal on the connection 330. The amplified signal drives the speaker 308. The voltage sense circuit 310 senses the voltage at the input of the speaker 308. The current sense circuit 312 senses the current at the input of the speaker 308. Any suitable circuit(s) is useful for the voltage sense circuit 310 and the current sense circuit 312. In examples, the voltage sense circuit 310 is a voltage divider, and the current sense circuit 312 is a shunt resistor. Other sensing topologies are contemplated and included in the scope of this description. The voltage sense circuit 310 may include an analog-to-digital converter (ADC) and may provide the sensed voltage on the connection 332 in digital form. The current sense circuit may include an ADC and may provide the sensed current on the connection 334 in digital form. The DSP 302 receives the sensed voltages and currents, rectifies the sensed voltages and currents in the digital domain, and calculates impedances using the rectified voltages and currents, as described above with reference to the impedance calculation circuitry 212. The DSP 302 applies bandpass filtering techniques to filter the calculated impedances by frequency band. The DSP 302 subsequently compares the filtered impedance values to the baseline impedance profile for the speaker 308, which may be stored in the memory 323. A comparison indicating a mismatch between any filtered impedance value and the corresponding impedance value from the baseline impedance profile indicates a speaker 210 error, that the incorrect sound was provided to the speaker 210, or both.

In some examples, the DSP 302 uses a predicted voltage Vpred instead of the sensed voltage, as described above with reference to FIG. 2. In such examples, the DSP 302 receives Vpred from any suitable external source, or the DSP 302 generates Vpred internally and uses the self-generated Vpred. For example, the speaker voltage prediction circuitry 202 (FIG. 2) is external to the DSP 302 or is part of the DSP 302. In either case, the DSP 302 applies a delay to the Vpred signal as described above with reference to FIG. 2 (e.g., delay circuitry 204). The DSP 302 uses the delayed Vpred signal with the sensed current signal to determine impedance values, as described herein.

Components depicted in FIG. 2 and described as “circuitry” may be implemented in the audio device 104 of FIG. 3 as hardware, software, firmware, or any combination thereof. For example, the sensing circuitry 208 is implemented as specific circuit components in the voltage sense circuit 310 (e.g., a voltage divider) and in the current sense circuit 312 (e.g., shunt resistor). For example, in the impedance calculation circuitry 212, bandpass filter circuitry 216, comparator circuitry 214, and other components are implemented as hardware components or as executable instructions 325 that are executed by the compute engine 321 to provide similar or identical operations as may be provided by hardware equivalents.

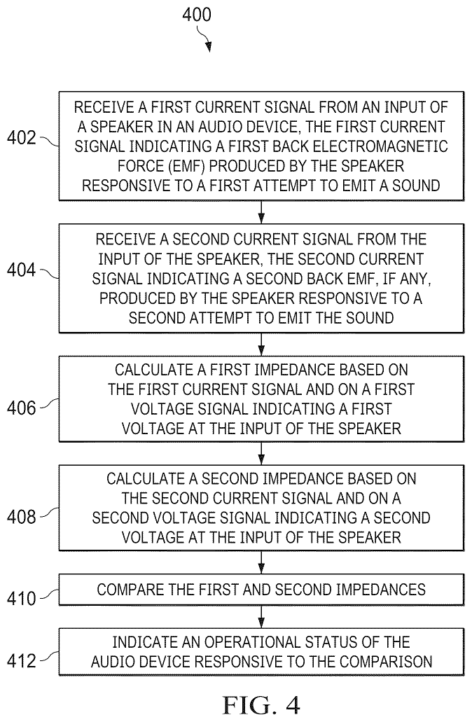

FIG. 4 is a flow diagram of a method 400 for determining a speaker status using back EMF changes, in various examples. The method 400 is performed by one or more components of the audio device 104 (FIGS. 3 and/or 4). The method 400 includes receiving a first current signal from an input of a speaker (e.g., the speaker 308) in an audio device (e.g., audio device 104) (402). The first current signal indicates a first back EMF produced by the speaker (e.g., the speaker 308) responsive to a first attempt to emit a sound (402). The method 400 includes receiving a second current signal from the input of the speaker (e.g., the speaker 308) (404). The second current signal indicates a second back EMF, if any, produced by the speaker (e.g., the speaker 308) responsive to a second attempt to emit the sound (404).

The method 400 includes calculating a first impedance based on the first current signal and on a first voltage signal indicating a first voltage at the input of the speaker (e.g., the speaker 308) (406). The method 400 includes calculating a second impedance based on the second current signal and on a second voltage signal indicating a second voltage at the input of the speaker (e.g., the speaker 308) (408). The method 400 includes comparing the first and second impedances (410). The method 400 includes indicating an operational status of the audio device (e.g., the audio device 104) responsive to the comparison (412).

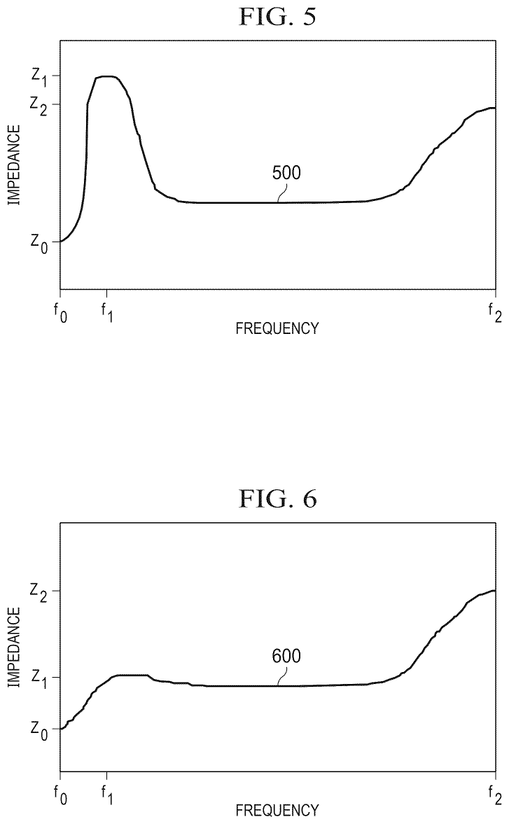

FIGS. 5 and 6 are graphs depicting impedance profiles useful to identify back EMF changes indicating a speaker status, in various examples. Specifically, FIG. 5 depicts an example baseline impedance profile 500, which is a curve plotting impedance as a function of frequency (e.g., the frequency of the sound provided by the speaker 308). The frequency f₀ is the low end of the frequency range, f₂ is the high end of the frequency range, and f₁ is the resonance frequency of the speaker 308. The impedances in the baseline impedance profile 500 range from Z₀ to Z₂, with an impedance Z₀ at frequency f₀, Z₁ at frequency f₁, and Z₂ at frequency f₂. The impedance profile 600 is identical to the impedance profile 500, except that at the resonance frequency f₁, the impedance in the impedance profile 600 is substantially less than the impedance in the impedance profile 500. This difference in impedance at the resonant frequency may be due to the altered back EMF caused by a fault in the speaker 308, or by a sound being played by the speaker 308 that does not match that played when the baseline impedance profile was produced. The audio device 104 produces an alert signal(s) accordingly, indicating operational status of the speaker 308, incorrect sound playback, or both.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

In this description, unless otherwise stated, “about,” “approximately” or “substantially” preceding a parameter means being within +/−10 percent of that parameter. Modifications are possible in the described examples, and other examples are possible within the scope of the claims.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device, or a semiconductor component. As used herein, “a connection” refers to a physical, electrically conductive component, such as a metal wire or trace, that facilitates the transfer of electrical signals between two or more other components.

What is claimed is:

1. A device, comprising:
audio amplifier circuitry having an input and an output, the output configured to couple to a speaker;
sense circuitry coupled to the output and configured to sense a voltage and a current of an analog audio signal from the audio amplifier circuitry, the current indicating a back electromotive force (EMF) of the speaker; and
processing circuitry coupled to the sense circuitry, the processing circuitry configured to:
calculate an impedance of a speaker based on the voltage and the current;
compare the impedance to a target impedance; and
indicate an operational status of the speaker responsive to the comparison.

2. The device of claim 1, wherein the processing circuitry is configured to indicate that at least one of the speaker and the analog audio signal is defective responsive to a mismatch between the impedance and the target impedance.

3. The device of claim 1, wherein the processing circuitry is configured to calculate multiple impedances based on multiple instances of the voltage and multiple instances of the current, the multiple impedances corresponding to multiple frequencies of audible sound attempted to be produced by the speaker.

4. The device of claim 3, wherein the processing circuitry is configured to filter the multiple impedances by frequency to produce filtered impedances.

5. The device of claim 4, wherein the voltage and the current correspond to a resonant frequency of the speaker.

6. The device of claim 1, wherein the processing circuitry is configured to rectify the voltage and the current.

7. A device comprising, comprising:
a processor configured to:
receive a first set of signals from an input of a speaker;
receive a second set of signals from the input of the speaker, the second set of signals generated subsequent to the first set of signals;
compare impedances calculated based on back electromotive forces (EMFs) in the first and second sets of signals; and
indicate that the speaker is defective responsive to the comparison.

8. The device of claim 7, wherein the processor is configured to receive the first set of signals while the speaker is in a non-defective state.

9. The device of claim 7, wherein the processor is configured to filter the impedances by frequency prior to comparing the impedances.

10. The device of claim 7, wherein the impedances correspond to a resonant frequency of the speaker.

11. The device of claim 7, wherein the processor is configured to rectify the first and second sets of signals prior to the comparison.

12. A non-transitory, computer-readable medium storing instructions, which, when executed by a processor, cause the processor to:
receive a first current signal from an input of a speaker in an audio device, the first current signal indicating a first back electromotive force (EMF) produced by the speaker responsive to a first attempt to emit a sound;
receive a second current signal from the input of the speaker, the second current signal indicating a second back EMF, produced by the speaker responsive to a second attempt to emit the sound;
calculate a first impedance based on the first current signal and on a first voltage signal indicating a first voltage at the input of the speaker;
calculate a second impedance based on the second current signal and on a second voltage signal indicating a second voltage at the input of the speaker;
compare the first and second impedances; and
indicate an operational status of the audio device responsive to the comparison.

13. The computer-readable medium of claim 12, wherein the instructions cause the processor to indicate that the speaker is defective responsive to a mismatch between the first and second impedances.

14. The computer-readable medium of claim 12, wherein the sound is a first sound, and wherein the instructions cause the processor to indicate, responsive to a mismatch between the first and second impedances, that the speaker emitted a second sound different from the first sound.

15. The computer-readable medium of claim 12, wherein the instructions cause the processor to:
capture the second current and voltage signals over a duration of the second attempt to emit the sound;
calculate a set of impedances based on the captured second current and voltage signals, the set of impedances corresponding to a range of frequencies of the sound.

16. The computer-readable medium of claim 15, wherein the instructions cause the processor to filter the set of impedances by frequency.

17. The computer-readable medium of claim 16, wherein the instructions cause the processor to isolate an impedance in the set of impedances that corresponds to a resonant frequency of the speaker.

18. The computer-readable medium of claim 12, wherein the second voltage signal is a voltage predicted to be at the input of the speaker.

19. The computer-readable medium of claim 18, wherein the instructions cause the processor to apply a time delay to the voltage predicted to be at the input of the speaker.

20. The computer-readable medium of claim 12, wherein the instructions cause the processor to rectify the first current and voltage signals.
